(19) United States
(12) Patent Application Publication
(10) Pub. No.: US 2026/0206328 A1
(43) Pub. Date: Jul. 16, 2026

(54) TANDEM SOLAR CELL, MANUFACTURING METHOD THEREOF, AND PHOTOVOLTAIC MODULE

(71) Applicant: LONGI GREEN ENERGY TECHNOLOGY CO., LTD., Xi'an (CN)

(72) Inventors: Chunxiu LI, Xi'an (CN); Chengjian HONG, Xi'an (CN); Shi YIN, Xi'an (CN); Minghao QU, Xi'an (CN); Xixiang XU, Xi'an (CN)

(21) Appl. No.: 19/138,510

(22) PCT Filed: Dec. 15, 2023
(86) PCT No.: PCT/CN2023/139251

§ 371 Date: Jun. 12, 2025

(30) Foreign Application Priority Data
Dec. 22, 2022 (CN) 202211659430.5

(51) Int. Cl. H10F 10/161; H10F 77/121; H10F 77/20

(52) U.S. Cl. CPC H10F 10/161; H10F 77/1215; H10F 77/219

(57) ABSTRACT

The present application discloses implementations relating to a tandem solar cell, a manufacturing method of a tandem solar cell, and a photovoltaic module. In an implementation, a tandem solar cell includes a bottom solar cell, a cadmium telluride top solar cell, an N-type transparent conductive layer, and a P-type transparent conductive layer. The cadmium telluride top solar cell is connected in series with the bottom solar cell, and a material of a back contact layer included in the cadmium telluride top solar cell includes at least one of copper-doped zinc telluride, copper-doped magnesium telluride, or copper-doped zinc nitride. The N-type transparent conductive layer and the P-type transparent conductive layer are sequentially stacked between the bottom solar cell and the cadmium telluride top solar cell along a direction from the bottom solar cell to the cadmium telluride top solar cell.

This application claims priority to Chinese Patent Application No. 202211659430.5, filed with the China National Intellectual Property Administration on Dec. 22, 2022 and entitled “TANDEM SOLAR CELL, MANUFACTURING METHOD THEREOF, AND PHOTOVOLTAIC MODULE”, which is incorporated herein by reference in its entirety.

### TECHNICAL FIELD

The present application relates to the field of solar cell technologies, and in particular, to a tandem solar cell, a manufacturing method thereof, and a photovoltaic module.

### BACKGROUND

A tandem solar cell is a solar cell structure formed by compounding a top solar cell and a bottom solar cell. The top solar cell is manufactured and formed by using a light transmissive material with a wide band gap. The bottom solar cell is manufactured and formed by using a light transmissive material with a narrow forbidden band width. Based on this, sunlight having a short wave length may be used by the top solar cell located above, and sunlight having a long wave length may be transmitted to the bottom solar cell through the top solar cell, and is used by the bottom solar cell. Therefore, the tandem solar cell can use sunlight with in a wide wave length range, and has a high light energy utilization.

However, in an existing tandem solar cell including a bottom solar cell and a cadmium telluride top solar cell, a back contact layer of the cadmium telluride solar cell has a poor carrier transport capability, which is not beneficial to improving electrical performance of the tandem solar cell.

### SUMMARY

An objective of the present application is to provide a tandem solar cell, a manufacturing method of a tandem solar cell, and a photovoltaic module, to enhance a carrier transport capability of a back contact layer included in a cadmium telluride cell, thereby facilitating improving electrical performance of the tandem solar cell.

To achieve the foregoing objective, the present application provides a tandem solar cell. The tandem solar cell includes: a bottom solar cell, a cadmium telluride top solar cell, an N-type transparent conductive layer, and a P-type transparent conductive layer.

The cadmium telluride top solar cell is located above the bottom solar cell and is connected in series with the bottom solar cell. A material of a back contact layer included in the cadmium telluride top solar cell includes at least one of copper-doped zinc telluride, copper-doped magnesium telluride, and copper-doped zinc nitride. The N-type transparent conductive layer and the P-type transparent conductive layer are sequentially stacked between the bottom solar cell and the cadmium telluride top solar cell along a direction from the bottom solar cell to the cadmium telluride top solar cell. A conductivity type of the N-type transparent conductive layer is the same as that of a front contact layer included in the bottom solar cell. A material of the P-type transparent conductive layer includes at least one of CuAlOx, BaCuSF, and CuI, and a concentration of copper ions on a side of the P-type transparent conductive layer facing toward a light-facing surface is greater than a concentration of copper ions on a side of the back contact layer included in the cadmium telluride top solar cell facing toward a back surface.

When the foregoing technical solution is used, the N-type transparent conductive layer and the P-type transparent conductive layer are sequentially stacked between the bottom solar cell and the cadmium telluride top solar cell along a direction from the bottom solar cell to the cadmium telluride top solar cell. In this case, the P-type transparent conductive layer is in contact with the back contact layer included in the cadmium telluride top solar cell. In addition, the material of the back contact layer included in the cadmium telluride top solar cell includes at least one of copper-doped zinc telluride, copper-doped magnesium telluride, and copper-doped zinc nitride. Because zinc telluride, magnesium telluride, and zinc nitride are all P-type semiconductor materials, a conductivity type of the back contact layer included in the cadmium telluride top solar cell is the same as that of the P-type transparent conductive layer. Moreover, the material of the P-type transparent conductive layer includes at least one of CuAlOx, BaCuSF, and CuI. Meanwhile, the concentration of the copper ions on the side of the P-type transparent conductive layer facing toward the light-facing surface is greater than the concentration of the copper ions on the side of the back contact layer included in the cadmium telluride top solar cell facing toward the back surface. In this case, in an actual manufacturing process, the P-type transparent conductive layer may be used as a doping source, so that copper ions included in the P-type transparent conductive layer diffuse at least into the back contact layer included in the cadmium telluride top solar cell, to increase a concentration of copper ions in the back contact layer included in the cadmium telluride top solar cell, thereby improving electrical conduction of the back contact layer included in the cadmium telluride top solar cell, and facilitating hole transport. In addition, contact between the back contact layer included in the cadmium telluride top solar cell and the P-type transparent conductive layer can also be improved, to optimize a field passivation effect of the back surface, and further improve electrical performance of the tandem solar cell.

In some embodiments, a light absorption layer included in the cadmium telluride top solar cell is doped with copper ions. The concentration of the copper ions on the side of the back contact layer included in the cadmium telluride top solar cell facing toward the light-facing surface is greater than the concentration of the copper ions on the side of the light absorption layer included in the cadmium telluride top solar cell facing toward the back surface.

When the foregoing technical solution is used, in an actual manufacturing process, the P-type transparent conductive layer may be used as a doping source, so that copper ions included in the P-type transparent conductive layer sequentially diffuse, along a direction facing toward the light-facing surface, into the back contact layer and the light absorption layer included in the cadmium telluride top solar cell, thereby improving electrical conduction of both the back contact layer and the light absorption layer included in the cadmium telluride top solar cell, and increasing a carrier concentration in the light absorption layer, so that the cadmium telluride top solar cell has good PN junction characteristics. This facilitates separation and transport of electrons and holes generated by the cadmium telluride top solar cell after the cadmium telluride top solar cell absorbs photons, and improves photoelectric conversion efficiency of the cadmium telluride top solar cell.

In some embodiments, a refractive index of the P-type transparent conductive layer is less than a refractive index of the back contact layer included in the cadmium telluride top solar cell. In this case, a reflectance on the back surface side of the cadmium telluride top solar cell can be reduced. This helps some photons refracted through the cadmium telluride top solar cell to the bottom solar cell to be absorbed, when the some photons enter the bottom solar cell, by photons reflected by the bottom solar cell to the cadmium telluride top solar cell, thereby improving utilization of short-wave sunlight by the cadmium telluride top solar cell.

In some embodiments, the refractive index of the P-type transparent conductive layer is less than a refractive index of the N-type transparent conductive layer. In this case, a reflectance on the light-facing surface side of the bottom solar cell can be reduced, so that more light transmitted through the cadmium telluride top solar cell can be refracted into the bottom solar cell, thereby improving utilization of long-wave sunlight by the bottom solar cell.

In some embodiments, a carrier concentration of the P-type transparent conductive layer is 8.0×1019 cm−3 to 3.0×1020.cm−3.

When the foregoing technical solution is used, a width of a space charge region depends on the carrier concentration in the semiconductor layer. Specifically, within a particular range, a higher carrier concentration in the semiconductor layer indicates a narrower width of the space charge region. Based on this, the carrier concentration of the P-type transparent conductive layer is in a range from 8.0×1019 cm−3 to 3.0×1020 cm−3. This can prevent the space charge region of a tunneling junction formed by the P-type transparent conductive layer and the N-type transparent conductive layer from being wide because of a small carrier concentration of the P-type transparent conductive layer, and facilitates tunneling of holes in the cadmium telluride top solar cell through the space charge region, thereby facilitating hole transport. In addition, the carrier concentration of the P-type transparent conductive layer is within this range, so that the P-type transparent conductive layer also has good electrical conduction, which helps improve an electron transport capability of the P-type transparent conductive layer.

In some embodiments, a thickness of the N-type transparent conductive layer is 115 nm to 135 nm.

When the foregoing technical solution is used, when a thickness of a film is one fourth of a wave length of light in the film, the film is an anti-reflection film, and has an anti-reflection effect on incident light. Based on this, a wave length of light transmitted through the cadmium telluride top solar cell is greater than 850 nm. In addition, the thickness of the N-type transparent conductive layer is 115 nm to 135 nm. In this case, the thickness of the N-type transparent conductive layer is equal to one fourth of the wave length of the light transmitted through the cadmium telluride top solar cell in the N-type transparent conductive layer, so that the N-type transparent conductive layer has an anti-reflection effect on the light, and more long-wave sunlight can be refracted into the bottom solar cell, thereby improving the utilization of long-wave sunlight by the bottom solar cell.

In some embodiments, a carrier concentration of the N-type transparent conductive layer is 8.0×1019 cm−3 to 3.0×1020 cm−3 . For beneficial effects in this case, refer to the analysis of beneficial effects of a case in which the carrier concentration of the P-type transparent conductive layer is 8.0×1019 cm−3 to 3.0×1020 cm−3 in the foregoing descriptions, and details are not described herein again.

In some embodiments, a material of the N-type transparent conductive layer is doped indium oxide and/or doped zinc oxide. A doping element of the doped indium oxide includes at least one of Sn, W, Ce, F, Zr, Ti, Ga, Zn, and H. A doping element in the doped zinc oxide includes at least one of Al, Ga, and H.

When the foregoing technical solution is used, because the doped indium oxide and the doped zinc oxide both have good light transmittance and electrical conduction, when the material of the N-type transparent conductive layer is the doped indium oxide and/or the doped zinc oxide, more long-wave sunlight can be refracted into the bottom solar cell, thereby improving the utilization of long-wave sunlight by the bottom solar cell, and an electronic transport capability of the N-type transparent conductive layer is also improved. In addition, a plurality of types of doping elements in both the doped indium oxide and the doped zinc oxide facilitate selecting a proper type based on different application scenarios, to improve applicability of the tandem solar cell provided in the present application in different application scenarios.

In some embodiments, along the direction from the bottom solar cell to the cadmium telluride top solar cell, the bottom solar cell includes a P-type doped silicon layer, an intrinsic silicon layer, an N-type silicon substrate, and an N-type doped silicon layer that are sequentially stacked. The N-type doped silicon layer is the front contact layer of the bottom solar cell, and the P-type doped silicon layer is the back contact layer of the bottom solar cell.

When the foregoing technical solution is used, the intrinsic silicon layer located on the back surface side of the N-type silicon substrate and the P-type doped silicon layer can form a heterogeneous contact structure. Based on this, because the heterogeneous contact structure has a passivation effect better than that of a tunneling passivated contact structure, when the heterogeneous contact structure is formed on the back surface side of the N-type silicon substrate, a carrier recombination rate at an interface between the N-type silicon substrate and the intrinsic silicon layer can be further reduced, thereby facilitating improving the photoelectric conversion efficiency of the bottom solar cell. In addition, compared with a P-type solar cell, conversion efficiency of an N-type solar cell is higher. Based on this, when the light absorption layer of the bottom solar cell is the N-type silicon substrate, the bottom solar cell can have higher conversion efficiency, so that the electrical performance of the tandem solar cell can be further improved.

In some embodiments, the N-type doped silicon layer is an N-type doped polycrystalline silicon layer. The bottom solar cell further includes a tunneling passivation layer located between the N-type silicon substrate and the N-type doped poly crystalline silicon layer.

When the foregoing technical solution is used, a tunneling passivated contact structure formed by the tunneling passivation layer located on the light-facing surface side of the N-type silicon substrate and the N-type doped polycrystalline silicon layer can achieve good interface passivation and selective carrier collection, thereby facilitating improving the photoelectric conversion efficiency of the bottom solar cell. In addition, because amorphous silicon and microcrystalline silicon materials have high light absorption coefficients, a heterogeneous contact structure manufactured by forming amorphous silicon and/or microcrystalline silicon materials on the light-facing surface side of the bottom solar cell may cause low utilization of light energy by the bottom solar cell due to severe parasitic absorption. However, the tunneling passivated contact structure generates weak parasitic absorption in a long-wave range, so that more long-wave sunlight transmitted through the cadmium telluride top solar cell can be refracted into the bottom solar cell through the tunneling passivated contact structure, thereby further improving the photoelectric conversion efficiency of the bottom solar cell.

In some embodiments, a doping concentration of a doping element in the P-type doped silicon layer gradually decreases along the direction from the bottom solar cell to the cadmium telluride top solar cell. In this case, a high-low junction may be formed in the P-type doped silicon layer along the direction from the bottom solar cell to the cadmium telluride top solar cell. In addition, a direction of a built-in electric field of the high-low junction is from a low doping concentration to a high doping concentration, that is, from the light-facing surface of the P-type doped silicon layer to the back surface. Based on this, because the direction of the built-in electric field of the high-low junction is consistent with a hole transport direction in the bottom solar cell, a hole transport capability of the P-type doped silicon layer can be enhanced, and the photoelectric conversion efficiency of the bottom solar cell can be further improved.

In some embodiments, a doping concentration of a doping element on a side of the P-type doped silicon layer facing away from the intrinsic silicon layer is 5.0×1020 cm−3 to 1.0×1022 cm−3 . In this case, a doping concentration of a doping element on a side of the P-type doped silicon layer facing away from the intrinsic silicon layer is high, which helps improve built-in electric field strength of the high-low junction in the P-type doped silicon layer, and further improve the hole transport capability of the P-type doped silicon layer.

In some embodiments, a doping concentration of a doping element on a side of the P-type doped silicon layer close to the intrinsic silicon layer is 1.0×1018 cm−3 to 5.0×1019 cm−3. In this case, the doping concentration of the doping element on the side of the P-type doped silicon layer close to the intrinsic silicon layer is low, which helps increase a difference between doping concentrations on two opposite surfaces of the P-type doped silicon layer along a thickness direction, to improve the built-in electric field strength of the high-low junction in the P-type doped silicon layer, and further improve the hole transport capability of the P-type doped silicon layer.

According to a second aspect, the present application further provides a photovoltaic module. The photovoltaic module includes the tandem solar cell provided in the first aspect and various implementations of the first aspect.

According to a third aspect, the present application further provides a manufacturing method of a tandem solar cell. The manufacturing method of a tandem solar cell includes the following steps:

A semiconductor substrate is formed.

An N-type transparent conductive layer and a P-type transparent conductive layer that are stacked are sequentially formed on a light-facing surface of the semiconductor substrate. A material of the P-type transparent conductive layer includes at least one of CuAlOx, BaCuSF, and CuI.

A cadmium telluride top solar cell is formed on the P-type transparent conductive layer.

Heat treatment is performed on the formed structure, so that copper ions in the P-type transparent conductive layer diffuse at least into a back contact layer included in the cadmium telluride top solar cell. A material of a back contact layer included in the cadmium telluride top solar cell includes at least one of copper-doped zinc telluride, copper-doped magnesium telluride, and copper-doped zinc nitride. A concentration of copper ions on a side of the P-type transparent conductive layer facing toward a light-facing surface is greater than a concentration of copper ions on a side of the back contact layer included in the cadmium telluride top solar cell facing toward a back surface.

A bottom solar cell is formed based on the semiconductor substrate. The cadmium telluride top solar cell is connected in series with the bottom solar cell. A conductivity type of the N-type transparent conductive layer is the same as that of a front contact layer included in the bottom solar cell.

In some embodiments, in the heat treatment process, the copper ions in the P-type transparent conductive layer further diffuse into a light absorption layer included in the cadmium telluride top solar cell. The light absorption layer included in the cadmium telluride top solar cell is doped with copper ions. A concentration of copper ions on a side of the back contact layer included in the cadmium telluride top solar cell facing toward the light-facing surface is greater than a concentration of copper ions on a side of the light absorption layer included in the cadmium telluride top solar cell facing toward the back surface.

In some embodiments, that a semiconductor substrate is formed includes the following steps: An N-type silicon substrate is provided. An N-type doped silicon layer is formed on a light-facing surface of the N-type silicon substrate.

That a bottom solar cell is formed based on the semiconductor substrate includes the following step: Along a direction away from the N-type silicon substrate, an intrinsic silicon layer and a P-type doped silicon layer that are sequentially stacked are formed on a back surface of the N-type silicon substrate. Along the direction from the bottom solar cell to the cadmium telluride top solar cell, the bottom solar cell includes the P-type doped silicon layer, the intrinsic silicon layer, the N-type silicon substrate, and the N-type doped silicon layer that are sequentially stacked.

When the foregoing technical solution is used, because a manufacturing temperature of a heterogeneous contact structure formed by the intrinsic silicon layer and the P-type doped silicon layer is low, and a forming temperature of the cadmium telluride top solar cell is high (approximately 500° C. to 700° C.), after the N-type transparent conductive layer, the P-type transparent conductive layer, and the cadmium telluride top solar cell are sequentially formed on the light-facing surface of the semiconductor substrate, the intrinsic silicon layer and the P-type doped silicon layer are then formed on the back surface of the semiconductor substrate, to prevent impact caused by high-temperature manufacturing to the intrinsic silicon layer and the P-type doped silicon layer, thereby ensuring that the heterogeneous contact structure formed by the intrinsic silicon layer and the P-type doped silicon layer has an excellent interface passivation effect and can achieve selective carrier collection. In addition, after the N-type doped silicon layer is formed on the light-facing surface of the N-type silicon substrate, the N-type transparent conductive layer, the P-type transparent conductive layer, and the cadmium telluride top solar cell are sequentially formed on the N-type doped silicon layer. Based on this, as described above, the forming temperature of the cadmium telluride top solar cell is high. Therefore, in a process of manufacturing the cadmium telluride top solar cell at a high temperature, the doping element in the N-type doped silicon layer can diffuse to the light-facing surface of the N-type silicon substrate, which facilitates smoother energy band transition between the N-type silicon substrate and the N-type doped silicon layer. Further, a field passivation effect on the light-facing surface side of the N-type silicon substrate can be improved, and photoelectric conversion efficiency of the bottom solar cell can be improved.

In some embodiments, the intrinsic silicon layer and the P-type doped silicon layer that are sequentially stacked on the back surface of the N-type silicon substrate are formed by using a low-temperature manufacturing process along the direction away from the N-type silicon substrate. A manufacturing temperature range of the low-temperature manufacturing process is 100° C. to 200° C. In this case, if the manufacturing temperature is within this range, an impact caused to the intrinsic silicon layer and the P-type doped silicon layer due to the high manufacturing process temperature can be prevented, thereby ensuring that the heterogeneous contact structure formed by the intrinsic silicon layer and the P-type doped silicon layer has an excellent interface passivation effect and can achieve selective carrier collection.

In some embodiments, the N-type doped silicon layer is an N-type doped polycrystalline silicon layer. In this case, after that an N-type silicon substrate is provided and before that an N-type doped silicon layer is formed on a light-facing surface of the N-type silicon substrate, the manufacturing method of a tandem solar cell further includes the following step: A tunneling passivation layer is formed on the light-facing surface of the N-type silicon substrate.

For beneficial effects of the second aspect and the third aspect and various implementations of the second aspect and the third aspect in the present application, refer to the analysis of the beneficial effects of the first aspect and various implementations of the first aspect, and details are not described herein again.

The foregoing descriptions are merely an overview of the technical solutions of the present application. To understand the technical means of the present application more clearly, implementation can be performed according to content of the specification. Moreover, to make the foregoing and other objectives, features, and advantages of the present application more comprehensible, specific implementations of the present application are particularly described below.

### BRIEF DESCRIPTION OF THE DRAWINGS

To describe the technical solutions in embodiments of the present application or in existing technologies more clearly, the accompanying drawings required for describing the embodiments or existing technologies are briefly described below. Apparently, the accompanying drawings in the following descriptions show some embodiments of the present application, and a person of ordinary skill in the art may still derive other drawings from these accompanying drawings without creative efforts.

The accompanying drawings described herein are used to provide a further understanding of the present application, and form a part of the present application. Exemplary embodiments of the present application and descriptions thereof are used to explain the present application, and do not constitute any inappropriate limitation to the present application. In the accompanying drawings:

FIG. 1 is a schematic structural longitudinal cross-sectional diagram of a tandem solar cell according to an embodiment of the present application;

FIG. 2 is a schematic structural diagram 1 of a tandem solar cell in a manufacturing process according to an embodiment of the present application;

FIG. 3 is a schematic structural diagram 2 of a tandem solar cell in a manufacturing process according to an embodiment of the present application;

FIG. 4 is a schematic structural diagram 3 of a tandem solar cell in a manufacturing process according to an embodiment of the present application;

FIG. 5 is a schematic structural diagram 4 of a tandem solar cell in a manufacturing process according to an embodiment of the present application;

FIG. 6 is a schematic structural diagram 5 of a tandem solar cell in a manufacturing process according to an embodiment of the present application;

FIG. 7 is a schematic structural diagram 6 of a tandem solar cell in a manufacturing process according to an embodiment of the present application;

FIG. 8 is a schematic structural diagram 7 of a tandem solar cell in a manufacturing process according to an embodiment of the present application;

FIG. 9 is a schematic structural diagram 8 of a tandem solar cell in a manufacturing process according to an embodiment of the present application; and

FIG. 10 is a schematic structural diagram 9 of a tandem solar cell in a manufacturing process according to an embodiment of the present application.

Reference numerals: 1: N-type silicon substrate, 2: tunneling passivation layer, 3: N-type doped silicon layer, 4: N-type transparent conductive layer, 5: P-type transparent conductive layer, 6: back contact layer included in a cadmium telluride top solar cell, 7: light absorption layer included in the cadmium telluride top solar cell, 8: window layer, 9: anti-reflection layer, 10: intrinsic silicon layer, 11: P-type doped silicon layer, 12: back surface transparent conductive layer, 13: positive electrode, and 14: negative electrode.

### DETAILED DESCRIPTION

To make the objectives, technical solutions, and advantages of embodiments of the present application clearer, the following clearly and completely describes the technical solutions in the embodiments of the present application with reference to the accompanying drawings in the embodiments of the present application. Apparently, the described embodiments are some of the embodiments of the present application rather than all the embodiments. All other embodiments obtained by a person of ordinary skill in the art based on the embodiments of the present application without creative efforts shall fall within the protection scope of the present application.

To make the technical problems to be resolved by, the technical solutions, and the beneficial effects of the present application clearer and more comprehensible, the following further describes the present application in detail with reference to the accompanying drawings and embodiments. It should be understood that, the specific embodiments described herein are merely used for describing the present application and are not used for limiting the present application.

The accompanying drawings show various schematic structural diagrams according to the embodiments of the present application. The accompanying drawings are not drawn to scale, some details are enlarged for the purpose of clarity, and some details may be omitted. Shapes of various regions and layers shown in the drawings, and relative sizes and positional relationships between the various regions and layers are merely exemplary, and may deviate in practice due to manufacturing tolerances or technical limitations, and a person skilled in the art may additionally design regions/layers with different shapes, sizes, and relative positions according to actual requirements.

In the context of the present disclosure, when a layer/element is referred to as being “on” another layer/element, the layer/element may be directly on the another layer/element, or an intermediate layer/element may exist between the layer/element and the another layer/element. In addition, if one layer/element is “above” another layer/element in an orientation, when the orientation is turned, the layer/element may be “below” the another layer/element. To make the technical problems to be resolved in the present application, the technical schemes, and beneficial effects more comprehensible, the following further describes the present invention in detail with reference to the accompanying drawings and the embodiments. It should be understood that the specific embodiments described herein are merely used to explain the present application but are not intended to limit the present application.

In addition, the terms “first” and “second” are used merely for the purpose of description, and shall not be construed as indicating or implying relative importance or implying a quantity of indicated technical features. Therefore, a feature defined by “first” or “second” may explicitly or implicitly include one or more features. In the descriptions of the present application, unless otherwise explicitly specified, “plurality of” means two or more than two. “Several” means one or more, unless otherwise definitely and specifically limited.

In the descriptions of the present application, it should be noted that, unless otherwise explicitly stipulated and restricted, terms “installation”, “joint connection”, and “connection” should be understood broadly, which, for example, may be a fixed connection, or may be a detachable connection, or an integral connection; or may be a mechanical connection, or may be an electrical connection; or may be a direct connection, or may be an indirect connection by using a medium, or may be an internal communication between two components, or may be an interactive relationship between two components. A person of ordinary skill in the art may understand the specific meanings of the foregoing terms in the present application according to specific situations.

The following describes the technical solutions of the present application in detail with reference to specific embodiments. The following specific embodiments may be mutually combined, and same or similar concepts or processes may not be repeatedly described in some embodiments.

A tandem solar cell is a solar cell structure formed by compounding a top solar cell and a bottom solar cell. The top solar cell is manufactured and formed by using a light transmissive material with a wide band gap. The bottom solar cell is manufactured and formed by using a light transmissive material with a narrow forbidden band width. Based on this, sunlight having a short wave length may be used by the top solar cell located above, and sunlight having a long wave length may be transmitted to the bottom solar cell through the top solar cell, and is used by the bottom solar cell. Therefore, the tandem solar cell can use sunlight with in a wide wave length range, and has a high light energy utilization.

However, in an existing tandem solar cell including a bottom solar cell and a cadmium telluride top solar cell, a back contact layer of the cadmium telluride solar cell has a poor carrier transport capability, which affects improvement of electrical performance of the tandem solar cell.

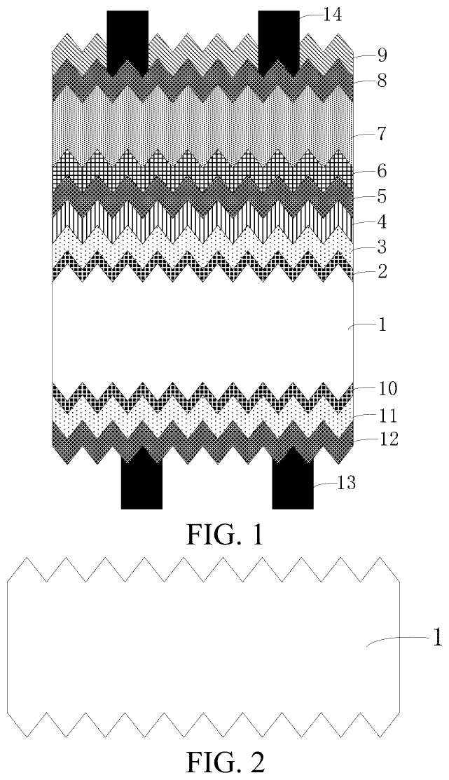

To resolve the foregoing technical problem, according to a first aspect, an embodiment of the present application provides a tandem solar cell. As shown in FIG. 1, the tandem solar cell includes a bottom solar cell, a cadmium telluride top solar cell, an N-type transparent conductive layer 4, and a P-type transparent conductive layer 5.

As shown in FIG. 1, the cadmium telluride top solar cell is located above the bottom solar cell and is connected in series with the bottom solar cell. A material of a back contact layer 6 included in the cadmium telluride top solar cell includes at least one of copper-doped zinc telluride, copper-doped magnesium telluride, and copper-doped zinc nitride. The N-type transparent conductive layer 4 and the P-type transparent conductive layer 5 are sequentially stacked between the bottom solar cell and the cadmium telluride top solar cell along a direction from the bottom solar cell to the cadmium telluride top solar cell. A conductivity type of the N-type transparent conductive layer 4 is the same as that of a front contact layer included in the bottom solar cell. A material of the P-type transparent conductive layer 5 includes at least one of CuAlOx, BaCuSF, and CuI, and a concentration of copper ions on a side of the P-type transparent conductive layer 5 facing toward a light-facing surface is greater than a concentration of copper ions on a side of the back contact layer 6 included in the cadmium telluride top solar cell facing toward a back surface.

Specifically, a type and a structure of the bottom solar cell may be set based on an actual requirement, provided that the bottom solar cell can be applied to the tandem solar cell provided in the embodiments of the present application. For example, the bottom solar cell may be a copper indium gallium selenide bottom solar cell, a crystalline silicon solar cell, or an amorphous silicon solar cell.

For the cadmium telluride top solar cell, as shown in FIG. 1, along a direction from the cadmium telluride top solar cell to the bottom solar cell, the cadmium telluride top solar cell may include a window layer 8, a light absorption layer, and a back contact layer. The window layer 8 and the back contact layer included in the cadmium telluride top solar cell have opposite conductivity types. In addition, a material of the back contact layer 6 included in the cadmium telluride top solar cell includes at least one of copper-doped zinc telluride, copper-doped magnesium telluride, and copper-doped zinc nitride. However, the foregoing zinc telluride, magnesium telluride, and zinc nitride are all P-type semiconductor materials. Therefore, a conductivity type of the window layer 8 is N-type.

Specifically, a material of the window layer may be any N-type semiconductor material, provided that the material can be applied to the tandem solar cell provided in the embodiments of the present application. For example, the material of the window layer may be doped indium oxide, or may be doped zinc oxide, or may be a mixed material of doped indium oxide and doped zinc oxide. A doping element of the doped indium oxide includes at least one of Sn, W, Ce, F, Zr, Ti, Ga, Zn, and H. A doping element in the doped zinc oxide includes at least one of Al, Ga, and H. In this case, because the doped indium oxide and the doped zinc oxide have high light transmittance and electrical conduction, when the material of the window layer is the doped indium oxide and/or the doped zinc oxide, more sunlight can be refracted from the window layer into the cadmium telluride top solar cell, thereby improving utilization of light energy by the cadmium telluride top solar cell, and further, an electron transport capability of the window layer can be improved, a separation rate of electrons and hole pairs at an interface between the light absorption layer and the window layer included in the cadmium telluride top solar cell is improved, carrier recombination is suppressed, and the photoelectric conversion efficiency of the cadmium telluride top solar cell is further improved.

A thickness of the window layer may be set based on an actual requirement, which is not specifically limited herein. For example, the thickness of the window layer may be 30 nm to 52 nm. Certainly, the thickness of the window layer may alternatively be set to another suitable value based on an actual application scenario requirement.

The light absorption layer included in the cadmium telluride top solar cell may be an absorption layer including any compound of Cd and Te, provided that the light absorption layer can be applied to the tandem solar cell provided in the embodiments of the present application. For example, a material of the light absorption layer included in the cadmium telluride top solar cell may include at least one of CdTe, CdSeTe, CdZnTe, CdMgTe, and CdMnTe. In addition, a thickness of the light absorption layer included in the cadmium telluride top solar cell is not specifically limited in the embodiments of the present application. For example, the thickness of the light absorption layer included in the cadmium telluride top solar cell may be 1 μm to 4 μm. In addition, the light absorption layer included in the cadmium telluride top solar cell may be an intrinsic layer, or may be a copper-doped light absorption layer. A concentration of copper ions in the copper-doped light absorption layer is not specifically limited.

A material of the back contact layer included in the cadmium telluride top solar cell may include only one of copper-doped zinc telluride, copper-doped magnesium telluride, and copper-doped zinc nitride; or may include any two of copper-doped zinc telluride, copper-doped magnesium telluride, and copper-doped zinc nitride; or may include all of copper-doped zinc telluride, copper-doped magnesium telluride, and copper-doped zinc nitride. When the material of the back contact layer includes more than two materials, a stochastic ratio between the different materials and a position distribution relationship between the different materials may be determined based on an actual application scenario, which is not specifically limited herein. In addition, a concentration of copper ions in the back contact layer included in the cadmium telluride top solar cell may alternatively be determine based on an actual application scenario, which is not specifically limited herein.

For the N-type transparent conductive layer, a material of the N-type transparent conductive layer may be indium tin oxide, fluorine-doped tin oxide, doped indium oxide, doped zinc oxide, or the like. In an embodiment, the material of the N-type transparent conductive layer is the doped indium oxide and/or the doped zinc oxide. A doping element of the doped indium oxide includes at least one of Sn, W, Ce, F, Zr, Ti, Ga, Zn, and H. A doping element in the doped zinc oxide includes at least one of Al, Ga, and H. In this case, when the foregoing technical solution is used, because the doped indium oxide and the doped zinc oxide both have good light transmittance and electrical conduction, when the material of the N-type transparent conductive layer is the doped indium oxide and/or the doped zinc oxide, more long-wave sunlight can be refracted into the bottom solar cell, thereby improving the utilization of long-wave sunlight by the bottom solar cell, and an electronic transport layer of the N-type transparent conductive layer is also improved. In addition, a plurality of types of doping elements in both the doped indium oxide and the doped zinc oxide facilitate selecting a proper type based on different application scenarios, to improve applicability of the tandem solar cell provided in the present application in different application scenarios.

A thickness of the N-type transparent conductive layer may be set based on an actual requirement. For example, the thickness of the N-type transparent conductive layer may be 115 nm to 135 nm. In this case, when a thickness of a film is one fourth of a wave length of light in the film, the film is an anti-reflection film, and has an anti-reflection effect on incident light. Based on this, a wave length of light transmitted through the cadmium telluride top solar cell is greater than 850 nm. In addition, the thickness of the N-type transparent conductive layer is 115 nm to 135 nm. In this case, the thickness of the N-type transparent conductive layer is equal to one fourth of the wave length of the light transmitted through the cadmium telluride top solar cell in the N-type transparent conductive layer, so that the N-type transparent conductive layer has an anti-reflection effect on the light, and more long-wave sunlight can be refracted into the bottom solar cell, thereby improving the utilization of long-wave sunlight by the bottom solar cell.

For the P-type transparent conductive layer, the material of the P-type transparent conductive layer may include only one of CuAlOx, BaCuSF, and CuI, or may include any two of CuAlOx, BaCuSF, and CuI, or may include all of CuAlOx, BaCuSF, and CuI. The foregoing P-type transparent conductive layers including the foregoing CuAlOx, BaCuSF, and CuI are all P-type transparent conductive layers including copper. In addition, as shown in FIG. 1, the P-type transparent conductive layer 5 is in contact with the back contact layer 6 included in the cadmium telluride top solar cell. Meanwhile, the concentration of the copper ions on the side of the P-type transparent conductive layer 5 facing toward the light-facing surface is greater than the concentration of the copper ions on the side of the back contact layer 6 included in the cadmium telluride top solar cell facing toward the back surface. In this case, in an actual manufacturing process, a diffusion direction is from a position with a high concentration to a position with a low concentration. Therefore, the P-type transparent conductive layer 5 may be used as a doping source, so that copper ions included in the P-type transparent conductive layer diffuse at least into the back contact layer 6 included in the cadmium telluride top solar cell, to increase a concentration of copper ions in the back contact layer 6 included in the cadmium telluride top solar cell, thereby improving electrical conduction of the back contact layer 6 included in the cadmium telluride top solar cell, and facilitating hole transport. In addition, contact between the back contact layer 6 included in the cadmium telluride top solar cell and the P-type transparent conductive layer 5 can also be improved, to optimize a field passivation effect of the back surface, and further improve electrical performance of the tandem solar cell.

In an actual application process, a difference between the concentration of the copper ions on the side of the P-type transparent conductive layer facing toward the light-facing surface and the concentration of the copper ions on the side of the back contact layer included in the cadmium telluride top solar cell facing toward the back surface may be determined based on requirements for electrical conduction of the P-type transparent conductive layer and the back contact layer included in the cadmium telluride top solar cell in an actual application scenario, and is not specifically limited herein.

In addition, as described above, the light absorption layer included in the cadmium telluride top solar cell may be doped with copper ions. Based on this, a concentration of copper ions on a side of the light absorption layer included in the cadmium telluride top solar cell facing toward the back surface may be less than or equal to a concentration of copper ions on a side of the back contact layer included in the cadmium telluride top solar cell facing toward the light-facing surface. When the concentration of the copper ions on the side of the back contact layer included in the cadmium telluride top solar cell facing toward the light-facing surface may be greater than the concentration of the copper ions on the side of the light absorption layer included in the cadmium telluride top solar cell facing toward the back surface, in an actual manufacturing process, the P-type transparent conductive layer may be used as a doping source, so that copper ions included in the P-type transparent conductive layer sequentially diffuse, along a direction facing toward the light-facing surface, into the back contact layer and the light absorption layer included in the cadmium telluride top solar cell, thereby improving electrical conduction of both the back contact layer and the light absorption layer included in the cadmium telluride top solar cell, so that the cadmium telluride top solar cell has good PN junction characteristics. This facilitates separation and transport of electrons and holes generated by the cadmium telluride top solar cell after the cadmium telluride top solar cell absorbs photons, and improves the photoelectric conversion efficiency of the cadmium telluride top solar cell.

In some embodiments, a refractive index of the P-type transparent conductive layer is less than a refractive index of the back contact layer included in the cadmium telluride top solar cell.

Specifically, the refractive indexes of the P-type transparent conductive layer and the back contact layer included in the cadmium telluride top solar cell may be set based on an actual requirement, which is not specifically limited herein. For example, the refractive index of the P-type transparent conductive layer may be approximately 1.7 to 1.88. The refractive index of the back contact layer included in the cadmium telluride top solar cell may be approximately 2.9 to 3.1. In an actual application process, when the materials of the P-type transparent conductive layer and the back contact layer included in the cadmium telluride top solar cell are determined, the refractive indexes of the P-type transparent conductive layer and the back contact layer included in the cadmium telluride top solar cell may be changed in a manner such as adjusting manufacturing processes and doping concentrations of the two film layers, so that the refractive index of the P-type transparent conductive layer is less than the refractive index of the back contact layer included in the cadmium telluride top solar cell, to reduce a reflectance on the back surface side of the cadmium telluride top solar cell. This helps some photons refracted through the cadmium telluride top solar cell to the bottom solar cell to be absorbed, when the some photons enter the bottom solar cell, by photons reflected by the bottom solar cell to the cadmium telluride top solar cell, thereby improving utilization of short-wave sunlight by the cadmium telluride top solar cell.

In some embodiments, the refractive index of the P-type transparent conductive layer is less than a refractive index of the N-type transparent conductive layer.

Specifically, for the refractive index of the P-type transparent conductive layer, refer to the foregoing descriptions, and details are not described herein again. The refractive index of the N-type transparent conductive layer may be set based on an actual requirement, provided that the refractive index of the N-type transparent conductive layer can be applied to the tandem solar cell provided in the embodiments of the present application. For example, the refractive index of the N-type transparent conductive layer may be approximately 1.9 to 2.3. In an actual application process, the refractive index of the N-type transparent conductive layer may be changed in a manner such as adjusting the material of the N-type transparent conductive layer, and manufacturing processes and doping concentrations of the P-type transparent conductive layer and the N-type transparent conductive layer, so that the refractive index of the P-type transparent conductive layer is less than the refractive index of the N-type transparent conductive layer, to reduce a reflectance on the light-facing surface side of the bottom solar cell, so that more light transmitted through the cadmium telluride top solar cell can be refracted into the bottom solar cell, thereby improving utilization of long-wave sunlight by the bottom solar cell.

In an actual application process, a tunneling junction may be formed between the N-type transparent conductive layer and the P-type transparent conductive layer that are sequentially stacked along the direction from the bottom solar cell to the cadmium telluride top solar cell. A width of a space charge region of the tunneling junction depends on carrier concentrations of the N-type transparent conductive layer and the P-type transparent conductive layer. Specifically, in a particular range, a lower carrier concentration of at least one of the N-type transparent conductive layer and the P-type transparent conductive layer indicates a larger width of the space charge region. On the contrary, higher carrier concentrations of the N-type transparent conductive layer and the P-type transparent conductive layer indicate a smaller width of the space charge region. In addition, a narrow space charge region facilitates hole transport. In this case, the carrier concentrations of the P-type transparent conductive layer and the N-type transparent conductive layer may be set based on a requirement for hole conduction and the like in an actual application scenario. This is not specifically limited herein.

For example, the carrier concentration of the P-type transparent conductive layer is 8.0×1019 cm−3 to 3.0×1020 cm−3 . In this case, when the carrier concentration of the P-type transparent conductive layer is in this range, this can prevent the space charge region of a tunneling junction formed by the P-type transparent conductive layer and the N-type transparent conductive layer from being wide because of a small carrier concentration of the P-type transparent conductive layer, and facilitates tunneling of holes in the cadmium telluride top solar cell through the space charge region, thereby facilitating hole transport. In addition, the carrier concentration of the P-type transparent conductive layer is within this range, so that the P-type transparent conductive layer also has good electrical conduction, which helps improve an electron transport capability of the P-type transparent conductive layer.

For example, the carrier concentration of the N-type transparent conductive layer is 8.0×1019 cm−3 to 3.0×1020cm−3. For beneficial effects in this case, refer to the analysis of beneficial effects of a case in which the carrier concentration of the P-type transparent conductive layer is 8.0×1019 cm−3 to 3.0×1020 cm−3 in the foregoing descriptions, and details are not described herein again.

In some embodiments, as described above, the bottom solar cell may be a crystalline silicon solar cell. A specific structure of the crystalline silicon solar cell may be set based on an actual requirement. From a perspective of passivation, the crystalline silicon solar cell may be a conventional crystalline silicon solar cell on which no passivated contact structure is formed. For example, the bottom solar cell may include a silicon substrate, an N-type doped silicon layer formed on a light-facing surface of the silicon substrate, and a P-type doped silicon layer formed on a back surface of the silicon substrate. The silicon substrate may be an intrinsic silicon substrate, may be an N-type silicon substrate, or may be a P-type silicon substrate.

Alternatively, the crystalline silicon solar cell may be a crystalline silicon solar cell on which a passivated contact structure is formed. In this case, a type of the passivated contact structure of the crystalline silicon solar cell may include only a tunneling passivated contact structure, or may include only a heterogeneous contact structure, or may include both a tunneling passivated contact structure and a heterogeneous contact structure.

When the type of the passivated contact structure of the crystalline silicon solar cell includes only the tunneling passivated contact structure, the tunneling passivated contact structure may be formed only on the light-facing surface side of the silicon substrate (where the tunneling passivated contact structure includes a tunneling passivation layer and an N-type doped polycrystalline silicon layer sequentially stacked along a direction away from the silicon substrate), or the tunneling passivated contact structure may be formed only on the back surface side of the silicon substrate (where the tunneling passivated contact structure includes a tunneling passivation layer and a P-type doped polycrystalline silicon layer sequentially stacked along the direction away from the silicon substrate), or the tunneling passivated contact structure may be formed on both the light-facing surface and the back surface of the silicon substrate.

When the type of the passivated contact structure of the crystalline silicon solar cell includes only the heterogeneous contact structure, the heterogeneous contact structure may be formed on only the back surface side of the silicon substrate. Based on this, a forming temperature of the cadmium telluride top solar cell is high, and the cadmium telluride top solar cell is formed on a light-facing surface side of the bottom solar cell. However, amorphous silicon and microcrystalline silicon materials easily form polycrystalline silicon or monocrystalline silicon at a high temperature. Therefore, in an actual manufacturing process, the heterogeneous contact structure may be formed on the back surface side of the silicon substrate after the cadmium telluride top solar cell is formed, thereby preventing an impact caused by a high-temperature process to a passivation effect of the heterogeneous contact structure.

For example, along the direction from the bottom solar cell to the cadmium telluride top solar cell, the bottom solar cell may include the P-type doped silicon layer, the intrinsic silicon layer, the N-type silicon substrate, and the N-type doped silicon layer that are sequentially stacked. The N-type doped silicon layer is the front contact layer of the bottom solar cell, and the P-type doped silicon layer is the back contact layer of the bottom solar cell. The intrinsic silicon layer located on the back surface side of the N-type silicon substrate and the P-type doped silicon layer can form a heterogeneous contact structure. Based on this, because the heterogeneous contact structure has a passivation effect better than that of a tunneling passivated contact structure, when the heterogeneous contact structure is formed on the back surface side of the N-type silicon substrate, a carrier recombination rate at an interface between the N-type silicon substrate and the intrinsic silicon layer can be further reduced, thereby facilitating improving the photoelectric conversion efficiency of the bottom solar cell. In addition, compared with a P-type solar cell, conversion efficiency of an N-type solar cell is higher. Based on this, when the light absorption layer of the bottom solar cell is the N-type silicon substrate, the bottom solar cell can have higher conversion efficiency, so that the electrical performance of the tandem solar cell can be further improved.

Specifically, the P-type doped silicon layer may be a P-type amorphous silicon layer, a P-type doped microcrystalline silicon layer, or a mixed layer of P-type doped amorphous silicon and microcrystalline silicon layers. A thickness of the P-type doped silicon layer may be 10 nm to 20 nm.

The intrinsic silicon layer may be an intrinsic amorphous silicon layer, an intrinsic microcrystalline silicon layer, or a mixed layer of intrinsic amorphous silicon and microcrystalline silicon layers. A thickness of the intrinsic silicon layer may be 5 nm to 10 nm.

A doping concentration of the N-type silicon substrate may be 3.0×1015 cm−3 to 1.0×1017 cm−3. In addition, a thickness of the N-type silicon substrate may be 90 μm to 150 μm. In this case, the thickness of the N-type silicon substrate is within this range, so that it can prevent a case in which a light absorption depth of the N-type silicon substrate is insufficient due to a small thickness of the N-type silicon substrate, to improve utilization of light energy by the N-type silicon substrate. In addition, a material waste and low efficiency caused by a large thickness of the N-type silicon substrate can also be avoided, thereby reducing manufacturing costs of the bottom solar cell. In addition, a light-facing surface and a back surface of the N-type silicon substrate may be flat polished surfaces. Alternatively, as shown in FIG. 1, the light-facing surface and the back surface of the N-type silicon substrate 1 may be textured surfaces. Based on this, because a textured structure has a light trapping function, when both the light-facing surface and the back surface of the N-type silicon substrate 1 are textured surfaces, reflectance of the two surfaces can be reduced, so that more light can be refracted from the two surfaces into the bottom solar cell, thereby improving the utilization of light energy by the bottom solar cell. In addition, because the cadmium telluride top solar cell is formed on the bottom solar cell, a surface of each film layer included in the cadmium telluride top solar cell also fluctuates accordingly, thereby further reducing reflectance of a light-facing surface of the cadmium telluride top solar cell, facilitating refracting more light into the cadmium telluride top solar cell, and improving utilization of light energy by the cadmium telluride top solar cell.

The N-type doped silicon layer may be an N-type doped polycrystalline silicon layer, an N-type doped monocrystalline silicon layer, or the like, which is not specifically limited herein. A thickness of the N-type doped silicon layer may be 100 nm to 200 nm. A doping concentration of the N-type doped silicon layer may be 7.0×1019 cm−3 to 1.0×1020 cm−3.

Apparently, the thicknesses of the P-type doped silicon layer, the intrinsic silicon layer, and the N-type doped silicon layer, and the doping concentrations of the N-type silicon substrate and the N-type doped silicon layer may alternatively be set to other suitable values based on requirements of actual application scenarios, and are not specifically limited herein.

When the type of the passivated contact structure of the crystalline silicon solar cell includes the tunneling passivated contact structure and the heterogeneous contact structure, as shown in FIG. 1, along the direction from the bottom solar cell to the cadmium telluride top solar cell, the bottom solar cell may include a P-type doped silicon layer 11, an intrinsic silicon layer 10, an N-type silicon substrate 1, a tunneling passivation layer 2, and an N-type doped polycrystalline silicon layer that are sequentially stacked. The N-type doped polycrystalline silicon layer is the front contact layer of the bottom solar cell, and the P-type doped silicon layer 11 is the back contact layer of the bottom solar cell. In this case, a tunneling passivated contact structure formed by the tunneling passivation layer 2 located on the light-facing surface side of the N-type silicon substrate 1 and the N-type doped polycrystalline silicon layer can achieve good interface passivation and selective carrier collection, thereby facilitating improving the photoelectric conversion efficiency of the bottom solar cell. In addition, because amorphous silicon and microcrystalline silicon materials have high light absorption coefficients, a heterogeneous contact structure manufactured by forming amorphous silicon and/or microcrystalline silicon materials on the light-facing surface side of the bottom solar cell may cause low utilization of light energy by the bottom solar cell due to severe parasitic absorption. However, the tunneling passivated contact structure generates weak parasitic absorption in a long-wave range, so that more long-wave sunlight transmitted through the cadmium telluride top solar cell can be refracted into the bottom solar cell through the tunneling passivated contact structure, thereby further improving the photoelectric conversion efficiency of the bottom solar cell.

Specifically, in this case, for materials and thicknesses of the P-type doped silicon layer and the intrinsic silicon layer, and materials and doping concentrations of the N-type silicon substrate and the N-type doped silicon layer, refer to the foregoing descriptions, and details are not described herein again. For the tunneling passivation layer, the material of the tunneling passivation layer may include one or more of silicon oxide, aluminum oxide, titanium oxide, hafnium oxide, gallium oxide, titanium pentoxide, niobium pentoxide, silicon nitride, silicon carbonitride, aluminum nitride, titanium nitride, or titanium carbonitride. A thickness of the tunneling passivation layer is not specifically limited in the embodiments of the present application. For example, the thickness of the tunneling passivation layer may be 1 nm to 5 nm.

In addition, regardless of whether the heterogeneous contact structure is formed only on the back surface of the bottom solar cell, or the tunneling passivation layer contact structure is formed on the light-facing surface of the bottom solar cell, a doping concentration of a doping element in the P-type doped silicon layer may gradually decrease along the direction from the bottom solar cell to the cadmium telluride top solar cell. In this case, a high-low junction may be formed in the P-type doped silicon layer along the direction from the bottom solar cell to the cadmium telluride top solar cell. In addition, a direction of a built-in electric field of the high-low junction is from a low doping concentration to a high doping concentration, that is, from the light-facing surface of the P-type doped silicon layer to the back surface. Based on this, because the direction of the built-in electric field of the high-low junction is consistent with a hole transport direction in the bottom solar cell, a hole transport capability of the P-type doped silicon layer can be enhanced, and the photoelectric conversion efficiency of the bottom solar cell can be further improved.

It may be understood that, within a particular range, a larger difference between doping concentrations of two opposite surfaces of the P-type doped silicon layer along the thickness direction indicates higher built-in electric field strength of the high-low junction in the P-type doped silicon layer, so that the hole transport capability of the P-type doped silicon layer can be further improved. Based on this, the doping concentrations of the doping element on the side of the P-type doped silicon layer away from the intrinsic silicon layer and the side of the P-type doped silicon layer close to the intrinsic silicon layer may be set based on a requirement for the hole transport capability of the P-type doped silicon layer in an actual application scenario. This is not specifically limited herein.

For example, the doping concentration of the doping element on the side of the P-type doped silicon layer facing away from the intrinsic silicon layer may be 5.0×1020 cm−3 to 1.0×1022 cm−3. In this case, the doping concentration of the doping element on the side of the P-type doped silicon layer facing away from the intrinsic silicon layer is high, which helps improve built-in electric field strength of the high-low junction in the P-type doped silicon layer, and further improve the hole transport capability of the P-type doped silicon layer.

For example, the doping concentration of the doping element on the side of the P-type doped silicon layer close to the intrinsic silicon layer is 1.0×1018 cm−3 to 5.0×1019cm−3. In this case, the doping concentration of the doping element on the side of the P-type doped silicon layer close to the intrinsic silicon layer is low, which helps increase a difference between doping concentrations on two opposite surfaces of the P-type doped silicon layer along a thickness direction, to improve the built-in electric field strength of the high-low junction in the P-type doped silicon layer, and further improve the hole transport capability of the P-type doped silicon layer.

In some cases, as shown in FIG. 1, the tandem solar cell further includes a positive electrode 13 and a negative electrode 14. The positive electrode 13 is formed on a light-facing surface side of the window layer 8 included in the cadmium telluride top solar cell. The negative electrode 14 is formed on a back surface side of the back contact layer included in the bottom solar cell. Specifically, materials of the positive electrode 13 and the negative electrode 14 may be conductive materials such as silver and/or copper.

In some cases, as shown in FIG. 1, the bottom solar cell further includes a back surface transparent conductive layer 12 formed on a side of the P-type doped silicon layer 11 facing away from the intrinsic silicon layer 10. In this case, because the P-type doped silicon layer 11 has poor transverse carrier mobility, and the back surface transparent conductive layer 12 has high electrical conduction, the back surface transparent conductive layer 12 formed on the side of the P-type doped silicon layer 11 facing away from the intrinsic silicon layer 10 facilitates transverse electron transport for further collection by the negative electrode 14. In addition, field passivation may be further performed on the back surface of the P-type doped silicon layer 11, to reduce a recombination rate of carriers on the back surface side of the P-type doped silicon layer 11, and improve the photoelectric conversion efficiency of the bottom solar cell.

A conductivity type of the back surface transparent conductive layer may be P-type, or may be N-type. In an actual application process, because a transparent conductive layer whose conductivity type is P-type is difficult to manufacture, and actual mobility thereof is not ideal, the conductivity type of the back surface transparent conductive layer is preferably N-type. In this case, for information such as a material and a thickness of the back surface transparent conductive layer, refer to the material and the thickness of the N-type transparent conductive layer described above, and details are not described herein again.

In some cases, as shown in FIG. 1, the cadmium telluride top solar cell further includes an anti-reflection layer 9 formed on a light-facing surface side of the window layer 8, so that more light is refracted into the tandem solar cell, thereby further improving the photoelectric conversion efficiency of the tandem solar cell.

A material of the anti-reflection layer may include at least one of magnesium fluoride, silicon oxide, silicon nitride, silicon, and aluminum oxide. Specifically, when the material of the anti-reflection layer includes at least two materials, a refractive index of the anti-reflection layer may gradually decrease along the direction from the cadmium telluride top solar cell to the bottom solar cell, to further reduce a reflectance on the light-facing surface side of the tandem solar cell. In addition, a thickness of the anti-reflection layer may be set based on an actual application scenario, which is not specifically limited herein. For example, the thickness of the anti-reflection layer may be 90 nm to 150 nm.

According to a second aspect, an embodiment of the present application further provides a photovoltaic module. The photovoltaic module includes the tandem solar cell provided in the first aspect and various implementations of the first aspect.

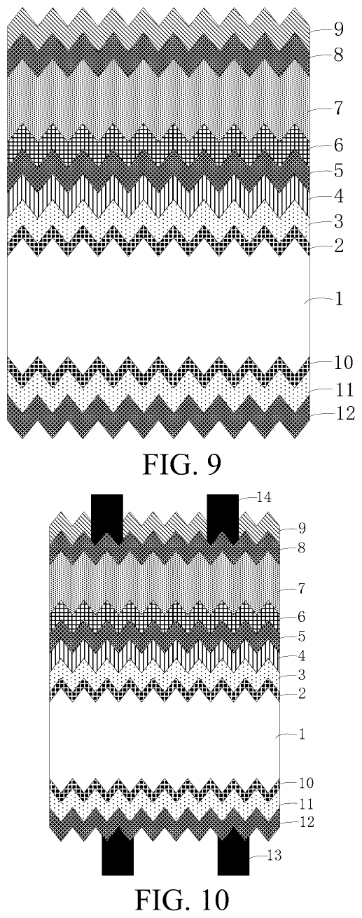

According to a third aspect, an embodiment of the present application further provides a manufacturing method of a tandem solar cell. A manufacturing process is described below with reference to cross-sectional views of operations shown in FIG. 2 to FIG. 10. Specifically, the manufacturing method of a tandem solar cell includes the following steps:

First, as shown in FIG. 3, a semiconductor substrate is formed.

Specifically, the semiconductor substrate is used for manufacturing a bottom solar cell included in the tandem solar cell. Therefore, a specific forming process of the semiconductor substrate may be determined based on a specific structure of the bottom solar cell.

For example, as described above, along a direction from the bottom solar cell to a cadmium telluride top solar cell, the bottom solar cell only includes a P-type doped silicon layer, an intrinsic silicon layer, an N-type silicon substrate, and an N-type doped silicon layer that are sequentially stacked. In this case, the semiconductor substrate may include an N-type silicon substrate and an N-type doped silicon layer. In this case, the N-type silicon substrate may be first provided. Next, the N-type doped silicon layer is formed on a light-facing surface of the N-type silicon substrate.

Specifically, in an actual application process, a process such as diffusion or ion implantation may be used to directly dope the light-facing surface of the N-type silicon substrate, to form the N-type doped silicon layer. Alternatively, a process such as low-pressure chemical vapor deposition may be first used to form an intrinsic silicon material layer on the light-facing surface of the N-type silicon substrate. Then, the intrinsic silicon material layer is doped to form an N-type doped silicon layer, to obtain the semiconductor substrate.

In addition, as described above, when the light-facing surface and the back surface of the N-type silicon substrate are both textured surfaces, texturing processing may further be performed on the N-type silicon substrate before the N-type doped silicon layer is formed. A tower base width of the textured surface may be set based on an actual requirement. For example, the tower base width of the textured surface may be 1 μm to 5 μm. In this case, the tower base width of the textured structure is within this range, so that reflectance of the light-facing surface and the back surface of the N-type silicon substrate can be reduced to between 11% and 13%, which is beneficial to increasing a short-circuit current of the bottom solar cell. In addition, in an actual manufacturing process, it is difficult for a textured surface to achieve a tower base width of less than 1 μm. Therefore, when the tower base width of the textured surface may be 1 μm to 5 μm, difficulty of the texturing processing can also be reduced.

For another example, as described above, along the direction from the bottom solar cell to the cadmium telluride top solar cell, the bottom solar cell may include a P-type doped silicon layer, an intrinsic silicon layer, an N-type silicon substrate, a tunneling passivation layer, and an N-type doped polycrystalline silicon layer that are sequentially stacked. In this case, the semiconductor substrate may include an N-type silicon substrate, a tunneling passivation layer, and an N-type doped polycrystalline silicon layer. In this case, as shown in FIG. 2, texturing processing may be first performed on the N-type silicon substrate 1 by using the foregoing manner. Next, a tunneling passivation layer 2 and an intrinsic silicon material layer located on the tunneling passivation layer 2 may be sequentially formed on the light-facing surface of the N-type silicon substrate 1 by using a process such as plasma enhanced chemical vapor deposition. Then, as shown in FIG. 3, the intrinsic silicon material layer may be doped by using a diffusion annealing process, an ion implantation process, or the like, so that the intrinsic silicon material layer forms an N-type doped silicon layer 3, thereby obtaining the semiconductor substrate.

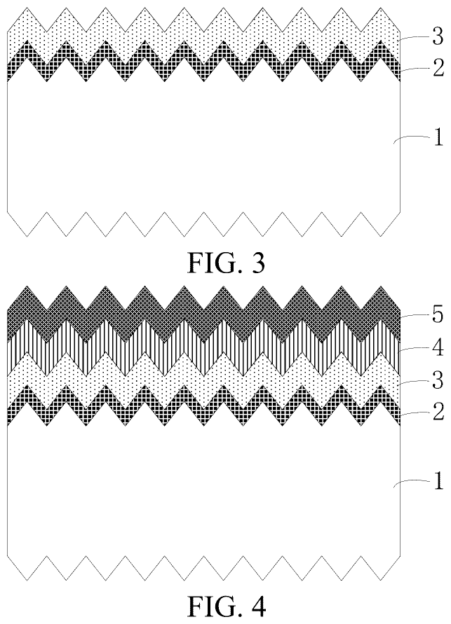

After the semiconductor substrate is formed, as shown in FIG. 4, an N-type transparent conductive layer 4 and a P-type transparent conductive layer 5 that are stacked are sequentially formed on a light-facing surface of the semiconductor substrate. A material of the P-type transparent conductive layer 5 includes at least one of CuAlOx, BaCuSF, and CuI.

Specifically, the N-type transparent conductive layer and P-type transparent conductive layer may be formed by using a process such as sputtering, reactive plasma deposition, or spray pyrolysis. For information such as materials, thicknesses, and carrier concentrations of the N-type transparent conductive layer and the P-type transparent conductive layer, refer to the foregoing descriptions, and details are not described herein again.

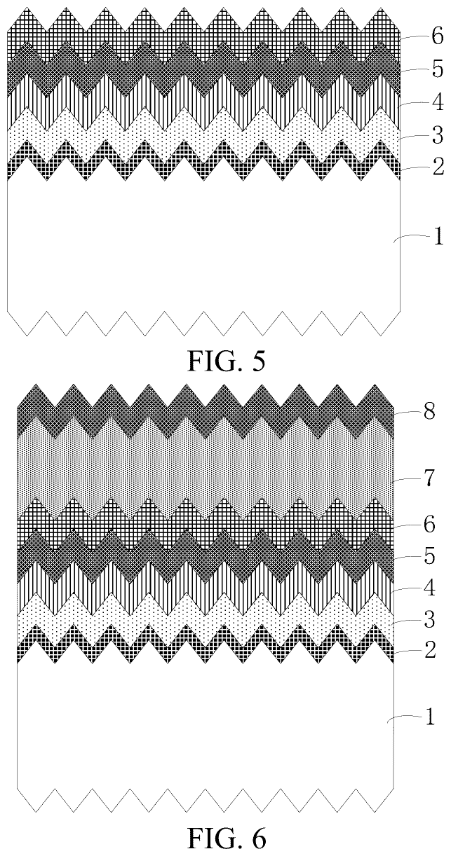

As shown in FIG. 5 and FIG. 6, a cadmium telluride top solar cell is formed on the P-type transparent conductive layer 5. In addition, heat treatment is performed on the formed structure, so that copper ions in the P-type transparent conductive layer 5 diffuse at least into a back contact layer 6 included in the cadmium telluride top solar cell. A material of the back contact layer 6 included in the cadmium telluride top solar cell includes at least one of copper-doped zinc telluride, copper-doped magnesium telluride, and copper-doped zinc nitride. A concentration of copper ions on a side of the P-type transparent conductive layer 5 facing toward a light-facing surface is greater than a concentration of copper ions on a side of the back contact layer 6 included in the cadmium telluride top solar cell facing toward a back surface.

For example, as shown in FIG. 5, the back contact layer 6 included in the cadmium telluride top solar cell may be formed on the P-type transparent conductive layer 5 by using a process such as thermal evaporation or sputtering. In this case, a concentration of copper ions in the back contact layer may be greater than or equal to 0, provided that the concentration is less than a concentration of copper ions in the back contact layer after the tandem solar cell is finally manufactured. Next, a light absorption layer 7 included in the cadmium telluride top solar cell may be formed by using a process such as steam transport or close space sublimation. Then, as shown in FIG. 6, a window layer 8 included in the cadmium telluride top solar cell may be formed by using a process such as sputtering, reactive plasma deposition, or spray pyrolysis, to obtain the cadmium telluride top solar cell. For information such as materials and thicknesses of the back contact layer 6, the light absorption layer, and the window layer 8 included in the cadmium telluride top solar cell, refer to the foregoing descriptions. Finally, heat treatment may be performed on the formed structure in a manner of annealing in a vacuum or a nitrogen atmosphere by using an annealing oven, so that copper ions in the P-type transparent conductive layer diffuse at least into the back contact layer included in the cadmium telluride top solar cell, to increase at least the concentration of the copper ions in the back contact layer included in the cadmium telluride top solar cell, thereby improving electrical conduction of the back contact layer included in the cadmium telluride top solar cell, and facilitating hole transport. In addition, contact between the back contact layer included in the cadmium telluride top solar cell and the P-type transparent conductive layer can also be improved, to optimize a field passivation effect of the back surface, and further improve electrical performance of the tandem solar cell. Specifically, conditions such as a processing temperature and processing time of the heat treatment may be set based on an actual requirement, which is not specifically limited herein.

It should be noted that, after the N-type doped silicon layer is formed on the light-facing surface of the N-type silicon substrate, the N-type transparent conductive layer, the P-type transparent conductive layer, and the cadmium telluride top solar cell are sequentially formed on the N-type doped silicon layer. Based on this, as described above, the forming temperature of the cadmium telluride top solar cell is high. Therefore, in a process of manufacturing the cadmium telluride top solar cell at a high temperature, the doping element in the N-type doped silicon layer can diffuse to the light-facing surface of the N-type silicon substrate, which facilitates smoother energy band transition between the N-type silicon substrate and the N-type doped silicon layer. Further, the field passivation effect on the light-facing surface side of the N-type silicon substrate can be improved, and photoelectric conversion efficiency of the bottom solar cell can be improved.

It should be noted that, as shown in FIG. 6, the formed structure includes the semiconductor substrate, the N-type transparent conductive layer 4, the P-type transparent conductive layer 5, and the cadmium telluride top solar cell.

In addition, as described above, when the light absorption layer included in the cadmium telluride top solar cell is a copper-doped light absorption layer, and a concentration of copper ions on a side of the light absorption layer included in the cadmium telluride top solar cell facing toward the back surface is less than a concentration of copper ions on a side of the back contact layer included in the cadmium telluride top solar cell facing toward the light-facing surface, after the heat treatment, copper ions in the P-type transparent conductive layer may sequentially diffuse into the back contact layer and the light absorption layer included in the cadmium telluride top solar cell. In this case, electrical conduction of both the back contact layer and the light absorption layer included in the cadmium telluride top solar cell can be improved, so that the cadmium telluride top solar cell has good PN junction characteristics. This facilitates separation and transport of electrons and holes generated by the cadmium telluride top solar cell after the cadmium telluride top solar cell absorbs photons, and improves the photoelectric conversion efficiency of the cadmium telluride top solar cell.

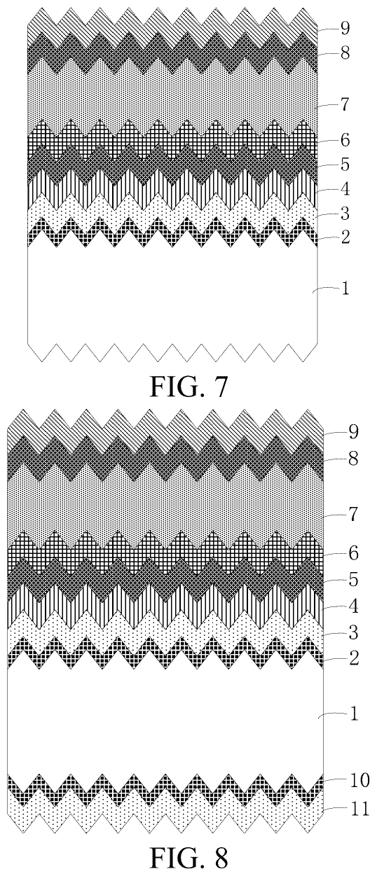

Further, as described above, when the cadmium telluride top solar cell further includes an anti-reflection layer, as shown in FIG. 7, after the window layer 8 is formed, and before the heat treatment, an anti-reflection layer 9 may be formed on the window layer 8 by using a process such as chemical vapor deposition. For information such as a material and a thickness of the anti-reflection layer 9, refer to the foregoing descriptions.

As shown in FIG. 8, the bottom solar cell is formed based on the semiconductor substrate. The cadmium telluride top solar cell is connected in series with the bottom solar cell. A conductivity type of the N-type transparent conductive layer 4 is the same as that of a front contact layer included in the bottom solar cell.

Specifically, a specific process of forming the bottom solar cell based on the semiconductor substrate may be determined based on a structure of the bottom solar cell.

For example, as described above, along the direction from the bottom solar cell to the cadmium telluride top solar cell, the bottom solar cell may include the P-type doped silicon layer, the intrinsic silicon layer, the N-type silicon substrate, and the N-type doped silicon layer that are sequentially stacked. In addition, the semiconductor substrate includes the N-type silicon substrate and the N-type doped silicon layer. In this case, that the bottom solar cell is formed based on the semiconductor substrate includes the following steps: As shown in FIG. 8, along a direction facing away from the N-type silicon substrate 1, an intrinsic silicon layer 10 and a P-type doped silicon layer 11 that are sequentially stacked may be formed on the back surface of the N-type silicon substrate 1 by using a process such as plasma enhanced chemical vapor deposition. Specifically, for materials and thicknesses of the intrinsic silicon layer 10 and the P-type doped silicon layer 11, refer to the foregoing descriptions.

When the foregoing technical solution is used, because a manufacturing temperature of a heterogeneous contact structure formed by the intrinsic silicon layer and the P-type doped silicon layer is low, and a forming temperature of the cadmium telluride top solar cell is high (approximately 500° C. to 700° C.), after the N-type transparent conductive layer, the P-type transparent conductive layer, and the cadmium telluride top solar cell are sequentially formed on the light-facing surface of the semiconductor substrate, the intrinsic silicon layer and the P-type doped silicon layer are then formed on the back surface of the semiconductor substrate, to prevent impact caused by high-temperature manufacturing to the intrinsic silicon layer and the P-type doped silicon layer, thereby ensuring that the heterogeneous contact structure formed by the intrinsic silicon layer and the P-type doped silicon layer has an excellent interface passivation effect and can achieve selective carrier collection.

It can be learned that the intrinsic silicon layer and the P-type doped silicon layer may be formed by using a low-temperature manufacturing process. A manufacturing temperature of the low-temperature manufacturing process may be set based on an actual requirement. For example, the manufacturing temperature range of the low-temperature manufacturing process may be 100° C. to 200° C. In this case, if the manufacturing temperature is within this range, an impact caused to the intrinsic silicon layer and the P-type doped silicon layer due to the high manufacturing process temperature can be prevented, thereby ensuring that the heterogeneous contact structure formed by the intrinsic silicon layer and the P-type doped silicon layer has an excellent interface passivation effect and can achieve selective carrier collection.

In some cases, as shown in FIG. 10, when the manufactured tandem solar cell further includes a back surface transparent conductive layer 12, after the P-type doped silicon layer 11 is formed, the back surface transparent conductive layer 12 may be formed on a side of the P-type doped silicon layer 11 facing away from the intrinsic silicon layer 10 by using a process such as sputtering, reactive plasma deposition, or spray pyrolysis. For information such as a material and a thickness of the back surface transparent conductive layer 12, refer to the foregoing descriptions.

Next, as shown in FIG. 10, a negative electrode 14 may be formed on a light-facing surface side of the cadmium telluride top solar cell, and a positive electrode 13 may be formed on a back surface side of the bottom solar cell by using a process such as screen printing, laser transfer printing, or electroplating, to obtain the tandem solar cell. For materials of the positive electrode 13 and the negative electrode 14, refer to the foregoing descriptions.

Finally, annealing processing may be further performed on the manufactured tandem solar cell, to crystallize each transparent conductive layer included in the tandem solar cell, and remove organics from the positive electrode and the negative electrode, thereby improving electrical conduction of each transparent conductive layer, the positive electrode, and the negative electrode. A temperature and time of the annealing processing may be set based on an actual requirement. For example, a temperature of the annealing processing may be 180° C. to 220° C., and annealing time is 30 min to 50 min.

In the foregoing descriptions, technical details such as composition and etching of each layer are not described in detail. However, a person skilled in the art should understand that a layer, a region, and the like of a required shape may be formed through various technical means. In addition, to form the same structure, a person skilled in the art may further design a method that is not exactly the same as the method described above. In addition, although the embodiments are separately described above, this does not mean that the measures in the embodiments cannot be advantageously used in combination.

The embodiments of the present application are described above. However, the embodiments are merely for illustrative purposes and are not intended to limit the scope of the present application. The scope of the present application is defined by the appended claims and equivalents thereof. A person skilled in the art may make various substitutes and modifications without departing from the scope of the present application, and the substitutes and modifications shall fall within the scope of the present application.

1. A tandem solar cell, comprising:
a bottom solar cell;
a cadmium telluride top solar cell, located above the bottom solar cell and connected in series with the bottom solar cell, wherein a material of a back contact layer comprised in the cadmium telluride top solar cell comprises at least one of copper-doped zinc telluride, copper-doped magnesium telluride, or copper-doped zinc nitride; and
an N-type transparent conductive layer and a P-type transparent conductive layer sequentially stacked between the bottom solar cell and the cadmium telluride top solar cell along a direction from the bottom solar cell to the cadmium telluride top solar cell, wherein a conductivity type of the N-type transparent conductive layer is same as that of a front contact layer comprised in the bottom solar cell, wherein a material of the P-type transparent conductive layer comprising at least one of CuAlOₓ, BaCuSF, or CuI, and wherein a concentration of copper ions on a side of the P-type transparent conductive layer facing toward a light-facing surface is greater than a concentration of copper ions on a side of the back contact layer comprised in the cadmium telluride top solar cell facing toward a back surface.

2. The tandem solar cell according to claim 1, wherein a light absorption layer comprised in the cadmium telluride top solar cell is doped with copper ions; and
a concentration of copper ions on a side of the back contact layer comprised in the cadmium telluride top solar cell facing toward the light-facing surface is greater than a concentration of copper ions on a side of the light absorption layer comprised in the cadmium telluride top solar cell facing toward the back surface.

3. The tandem solar cell according to claim 1, wherein a refractive index of the P-type transparent conductive layer is less than at least one of a refractive index of the back contact layer comprised in the cadmium telluride top solar cell or a refractive index of the N-type transparent conductive layer.

4. The tandem solar cell according to claim 1, wherein a carrier concentration of the P-type transparent conductive layer is between 8.0×10¹⁹ cm⁻³ and 3.0×10²⁰ cm⁻³.

5. The tandem solar cell according to claim 1, wherein a thickness of the N-type transparent conductive layer is between 115 nm and 135 nm; or
a carrier concentration of the N-type transparent conductive layer is between 8.0×10¹⁹ cm⁻³ and 3.0×10²⁰ cm⁻³; or
a material of the N-type transparent conductive layer is doped indium oxide or doped zinc oxide, wherein a doping element of the doped indium oxide comprises at least one of Sn, W, Ce, F, Zr, Ti, Ga, Zn, or H, and wherein a doping element in the doped zinc oxide comprises at least one of Al, Ga, or H.

6. The tandem solar cell according to claim 1, wherein along the direction from the bottom solar cell to the cadmium telluride top solar cell, the bottom solar cell comprises a P-type doped silicon layer, an intrinsic silicon layer, an N-type silicon substrate, and an N-type doped silicon layer that are sequentially stacked, wherein the N-type doped silicon layer is the front contact layer of the bottom solar cell, and wherein the P-type doped silicon layer is a back contact layer of the bottom solar cell.

7. The tandem solar cell according to claim 6, wherein the N-type doped silicon layer is an N-type doped polycrystalline silicon layer, and wherein the bottom solar cell further comprises a tunneling passivation layer located between the N-type silicon substrate and the N-type doped polycrystalline silicon layer.

8. The tandem solar cell according to claim 6, wherein a doping concentration of a doping element in the P-type doped silicon layer decreases along the direction from the bottom solar cell to the cadmium telluride top solar cell.

9. The tandem solar cell according to claim 8, wherein a doping concentration of a doping element on a side of the P-type doped silicon layer facing away from the intrinsic silicon layer is between 5.0×10²⁰ cm⁻³ and 1.0×10²² cm⁻³; and/or
a doping concentration of a doping element on a side of the P-type doped silicon layer close to the intrinsic silicon layer is between 1.0×10¹⁸ cm⁻³ and 5.0×10¹⁹cm⁻³.

10. A photovoltaic module, the photovoltaic module comprising a tandem solar cell, wherein the tandem solar cell comprising:
a bottom solar cell;
a cadmium telluride top solar cell, located above the bottom solar cell and connected in series with the bottom solar cell, wherein a material of a back contact layer comprised in the cadmium telluride top solar cell comprises at least one of copper-doped zinc telluride, copper-doped magnesium telluride, or copper-doped zinc nitride; and
an N-type transparent conductive layer and a P-type transparent conductive layer sequentially stacked between the bottom solar cell and the cadmium telluride top solar cell along a direction from the bottom solar cell to the cadmium telluride top solar cell, wherein a conductivity type of the N-type transparent conductive layer is same as that of a front contact layer comprised in the bottom solar cell, wherein a material of the P-type transparent conductive layer comprising at least one of CuAlOₓ, BaCuSF, or CuI, and wherein a concentration of copper ions on a side of the P-type transparent conductive layer facing toward a light-facing surface is greater than a concentration of copper ions on a side of the back contact layer comprised in the cadmium telluride top solar cell facing toward a back surface.

11. A manufacturing method of a tandem solar cell, comprising:
forming a semiconductor substrate;
sequentially forming an N-type transparent conductive layer and a P-type transparent conductive layer that are stacked on a light-facing surface of the semiconductor substrate wherein a material of the P-type transparent conductive layer comprises at least one of CuAlOₓ, BaCuSF, or CuI;
forming a cadmium telluride top solar cell on the P-type transparent conductive layer;
performing heat treatment that causes copper ions in the P-type transparent conductive layer diffuse at least into a back contact layer comprised in the cadmium telluride top solar cell, wherein a material of the back contact layer comprised in the cadmium telluride top solar cell comprising at least one of copper-doped zinc telluride, copper-doped magnesium telluride, or copper-doped zinc nitride, and wherein a concentration of copper ions on a side of the P-type transparent conductive layer facing toward a light-facing surface is greater than a concentration of copper ions on a side of the back contact layer comprised in the cadmium telluride top solar cell facing toward a back surface; and
forming a bottom solar cell based on the semiconductor substrate, wherein the cadmium telluride top solar cell being connected in series with the bottom solar cell, and wherein a conductivity type of the N-type transparent conductive layer is same as that of a front contact layer comprised in the bottom solar cell.

12. The manufacturing method of a tandem solar cell according to claim 11, wherein the heat treatment further causes the copper ions in the P-type transparent conductive layer to diffuse into a light absorption layer comprised in the cadmium telluride top solar cell, wherein copper ions are doped in the light absorption layer comprised in the cadmium telluride top solar cell, and wherein a concentration of copper ions on a side of the back contact layer comprised in the cadmium telluride top solar cell facing toward the light-facing surface is greater than a concentration of copper ions on a side of the light absorption layer comprised in the cadmium telluride top solar cell facing toward the back surface.

13. The manufacturing method of a tandem solar cell according to claim 11, wherein the forming a semiconductor substrate comprises:
providing an N-type silicon substrate; and
forming an N-type doped silicon layer on a light-facing surface of the N-type silicon substrate;
wherein the forming a bottom solar cell based on the semiconductor substrate comprises:
forming, along a direction away from the N-type silicon substrate, an intrinsic silicon layer and a P-type doped silicon layer that are sequentially stacked on a back surface of the N-type silicon substrate; and
wherein along the direction from the bottom solar cell to the cadmium telluride top solar cell, the bottom solar cell comprises the P-type doped silicon layer, the intrinsic silicon layer, the N-type silicon substrate, and the N-type doped silicon layer that are sequentially stacked.

14. The manufacturing method of a tandem solar cell according to claim 13, wherein the intrinsic silicon layer and the P-type doped silicon layer are formed by using a low-temperature manufacturing process along the direction away from the N-type silicon substrate, and wherein a manufacturing temperature range of the low-temperature manufacturing process is 100° C. to 200°C.

15. The manufacturing method of a tandem solar cell according to claim 13, wherein the N-type doped silicon layer is an N-type doped polycrystalline silicon layer, and wherein the manufacturing method further comprises:
after the providing an N-type silicon substrate and before the forming an N-type doped silicon layer on a light-facing surface of the N-type silicon substrate, forming a tunneling passivation layer on the light-facing surface of the N-type silicon substrate.

16. The photovoltaic module according to claim 10, wherein a light absorption layer comprised in the cadmium telluride top solar cell is doped with copper ions; and
a concentration of copper ions on a side of the back contact layer comprised in the cadmium telluride top solar cell facing toward the light-facing surface is greater than a concentration of copper ions on a side of the light absorption layer comprised in the cadmium telluride top solar cell facing toward the back surface.

17. The photovoltaic module according to claim 10, wherein a refractive index of the P-type transparent conductive layer is less than at least one of a refractive index of the back contact layer comprised in the cadmium telluride top solar cell or a refractive index of the N-type transparent conductive layer.

18. The photovoltaic module according to claim 10, wherein a carrier concentration of the P-type transparent conductive layer is between 8.0×10¹⁹ cm⁻³ and 3.0×10²⁰cm⁻³.

19. The photovoltaic module according to claim 10, wherein a thickness of the N-type transparent conductive layer is between 115 nm and 135 nm; or a carrier concentration of the N-type transparent conductive layer is between 8.0×10¹⁹ cm⁻³ and 3.0×10²⁰ cm⁻³; or a material of the N-type transparent conductive layer is doped indium oxide or doped zinc oxide, wherein a doping element of the doped indium oxide comprises at least one of Sn, W, Ce, F, Zr, Ti, Ga, Zn, or H, and wherein a doping element in the doped zinc oxide comprises at least one of Al, Ga, or H.

20. The photovoltaic module according to claim 10, wherein along the direction from the bottom solar cell to the cadmium telluride top solar cell, the bottom solar cell comprises a P-type doped silicon layer, an intrinsic silicon layer, an N-type silicon substrate, and an N-type doped silicon layer that are sequentially stacked, wherein the N-type doped silicon layer is the front contact layer of the bottom solar cell, and wherein the P-type doped silicon layer is a back contact layer of the bottom solar cell.
